(19) United States
(12) Patent Application Publication
(10) Pub. No.: US 2026/0267240 A1
(43) Pub. Date: Sep. 10, 2026

(54) METHOD AND SYSTEM FOR TEMPERATURE CONTROLLING IN LITHOGRAPHY PROCESS

(71) Applicant: TAIWAN SEMICONDUCTOR MANUFACTURING COMPANY, LTD., Hsinchu (TW)

(72) Inventors: Isha DATYE, San Carlos, CA (US); Xiaheng HUANG, Sunnyvale, CA (US); Sam VAZIRI, San Jose, CA (US); Chia-Tung KUO, Hsinchu City (TW); Huan-Ling LEE, Hsinchu County (TW); Xinyu BAO, Fremont, CA (US)

(73) Assignee: TAIWAN SEMICONDUCTOR MANUFACTURING COMPANY, LTD., Hsinchu (TW)

(21) Appl. No.: 19/074,022

(22) Filed: Mar. 7, 2025

(51) Int. Cl. G03F 7/00; G01K 1/16; G01K 3/00; G03F 1/62; H01L 21/67

(52) U.S. Cl. CPC G03F 7/70875; G01K 1/16; G01K 3/005; G03F 1/62; G03F 7/70525; G03F 7/70591; G03F 7/7085; H10P 72/0602

(57) ABSTRACT

A method includes receiving a semiconductor substrate to a substrate stage of a lithography system. A photomask with a membrane of a pellicle formed on the photomask is loaded to a mask stage of the lithography system. Light is illuminated, by using a light source of the lithography system, on the membrane and the photomask to perform an exposure process on the semiconductor substrate. A temperature of the membrane of the pellicle is obtained during performing the exposure process. The membrane is heated if the obtained temperature of the membrane is less than a predetermined temperature.

### BACKGROUND

In the semiconductor integrated circuit (IC) industry, technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of IC processing and manufacturing.

In a process of manufacturing the IC devices, a lithography process is employed to form a circuit pattern on a wafer. In the lithography process, a photomask is used to transfer a desired pattern onto the wafer. When the photomask is contaminated with foreign materials, such as particles, from the ambient environment, defects may occur on the wafer to which the pattern of the photomask is transferred.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a manufacturing system including a lithography system, a photomask, and a pellicle, in accordance with some embodiments.

FIGS. 2A and 2B are cross-sectional views of the pellicle, the photomask, and the control device of FIG. 1, according to some embodiments of the present disclosure.

FIG. 2C is a top view of the pellicle and the control device of FIG. 2A.

FIG. 3 is a flowchart illustrating a method for temperature controlling of the membrane in accordance with some embodiments.

FIG. 4 is a graph illustrating maximum temperatures Tₘₐₓ, minimum temperatures Tₘᵢₙ, and temperature differences ΔT between the maximum temperatures and the minimum temperatures of the membrane under different background temperatures.

FIGS. 5A-5B are partial views of the pellicle and the control device during various stages of processing the temperature controlling according to the method.

FIGS. 6A-8B illustrate top views and cross-sectional views of intermediate stages in the formation of a test device in accordance with some embodiments of the present disclosure.

FIG. 9 is a plot of electrical resistance vs. temperature of the test devices with difference channel lengths and/or channel widths.

FIGS. 10A-14B illustrate top views and cross-sectional views of intermediate stages in the formation of a test device in accordance with some embodiments of the present disclosure.

FIG. 15 is a plot of electrical resistance vs. temperature of the test devices with difference channel lengths and/or channel widths.

FIGS. 16 and 17 illustrate a computer system for applying current to the individual conductive electrodes in accordance with various embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “above”, “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around”, “about”, “approximately”, or “substantially” shall generally mean within 20 percent, or within 10 percent, or within 5 percent of a given value or range. Numerical quantities given herein are approximate, meaning that the term “around”, “about”, “approximately”, or “substantially” can be inferred if not expressly stated. One of ordinary skill in the art will appreciate that the dimensions may be varied according to different technology nodes. One of ordinary skill in the art will recognize that the dimensions depend upon the specific device type, technology generation, minimum feature size, and the like. It is intended, therefore, that the term be interpreted in light of the technology being evaluated.

The advanced lithography process, method, and materials described in the current disclosure can be used in many applications, including fin-type field effect transistors (FinFETs). For example, the fins may be patterned to produce a relatively close spacing between features, for which the above disclosure is well suited. In addition, spacers used in forming fins of FinFETs can be processed according to the above disclosure.

Photolithographic patterning processes use a photomask that includes a desired mask pattern. The photomask may be a reflective mask or a transmission mask. In the process, ultraviolet light is reflected off the surface of the photomask (for a reflective mask) or transmitted through the photomask (for a transmission mask) to transfer the pattern to a photoresist on a semiconductor wafer. The exposed portion of the photoresist is photochemically modified. After the exposure, the photoresist is developed to define openings in the photoresist, and one or more semiconductor processing operations (e.g., etching, epitaxial layer deposition, metallization, etc.) are performed which operate on those areas of the wafer surface exposed by the openings in the photoresist. After this semiconductor processing, the photoresist is removed by a suitable resist stripper or the like.

The minimum feature size of the pattern is limited by the light wavelength. Deep ultraviolet (UV) lithography, for example using a wavelength of 193 nm or 248 nm in some standard deep UV platforms, typically employs transmission masks and provides a smaller minimum feature size than lithography at longer wavelengths. Extreme ultraviolet (EUV) light, which spans wavelengths from 124 nm down to 10 nm, is currently being used to provide even smaller minimum feature size. At shorter wavelengths, particle contaminants on the photomask can cause defects in the transferred pattern. Thus, a pellicle is used to protect the photomask from such particle contaminants. The pellicle includes a pellicle membrane which is attached to a mounting frame. The mounting frame supports the pellicle membrane over the photomask. Any contaminating particles which land on the pellicle membrane are kept out of the focal plane of the photomask. As a result, defects in the transferred pattern are reduced or prevented.

Some embodiments of the present disclosure are related to methods for in-situ temperature controlling of the pellicle membrane during lithography or exposure processes. More specifically, some embodiments of the present disclosure are related to dynamic heating the pellicle membrane during the lithography or exposure processes to prevent the pellicle membrane from suffering thermal stress, which leads to cracking or wrinkling issues of the pellicle membrane.

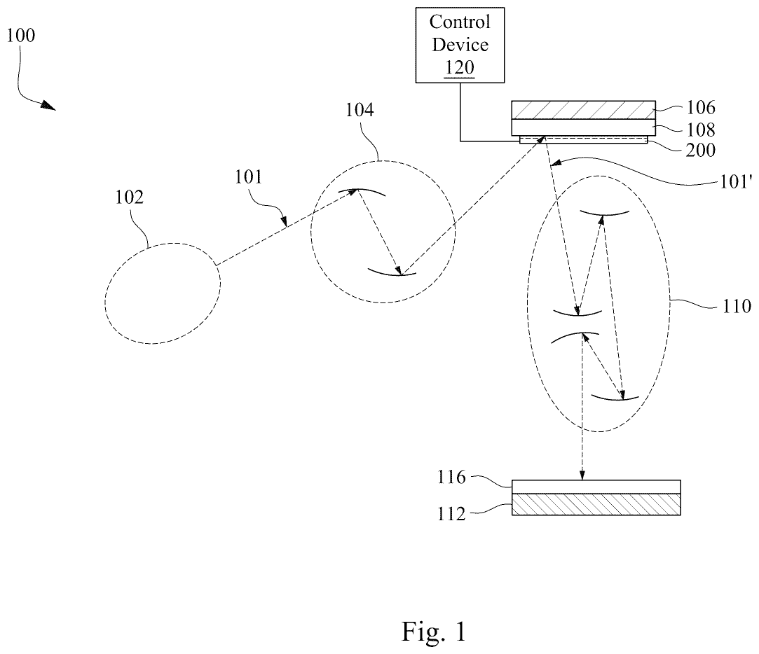

FIG. 1 is a schematic diagram of a manufacturing system including a lithography system 100, a photomask 108, and a pellicle 200, in accordance with some embodiments. The lithography system 100 may also be referred to as a “scanner” that is operable to perform lithographic processes including exposure with a respective radiation source and in particular exposure modes. In some embodiments, the lithography system 100 includes a light source 102, an illuminator 104, a mask stage 106, a projection optics module 110, a substrate stage 112, and a control device 120. In some embodiments, the lithography system 100 may include additional components that are not illustrated in FIG. 1. In some embodiments, one or more of the light source 102, the illuminator 104, the mask stage 106, the photomask 108, the projection optics module 110, and the substrate stage 112 may be omitted from the lithography system 100 or may be integrated into combined components.

The light source 102 may be configured to emit high-brightness radiation (or light) 101 having wavelengths in the range of approximately 1 nanometer (nm) to 250 nm. In some embodiments, the light source 102 generates EUV light with a wavelength centered at approximately 13.5 nm; accordingly, in some embodiments, the light source 102 may also be referred to as an “EUV light source.” However, it will be appreciated that the light source 102 should not be limited to emitting EUV light. For instance, the light source 102 may be utilized to perform any high-intensity photon emission from excited target material. In some embodiments, the light source 102 may be an i-line, G-line, 248 nm, 193 nm, deep ultraviolet (DUV), sub-EUV, soft X-ray, or X-ray high source.

In embodiments where the lithography system 100 is a UV lithography system, the illuminator 104 may include various refractive optical components, such as a single lens or a lens system comprising multiple lenses (zone plates). In some embodiments, the illuminator 104 may include a mirror, concave mirror, convex mirror, lens, pellicle mirror, beam splitter, semi-transparent mirror, waveguide, dynamic gas lock (DGL) membrane. In embodiments where the lithography system 100 is an EUV lithography system, the illuminator 104 may include various reflective optical components, such as a single mirror or a mirror system including multiple mirrors. The illuminator 104 may direct light 101 from the light source 102 onto the mask stage 106, and more particularly onto the photomask 108 that is secured onto the mask stage 106. In embodiments where the light source 102 generates light 101 in the EUV wavelength range, the illuminator 104 includes reflective optics.

The mask stage 106 may be configured to secure the photomask 108. In some embodiments, the mask stage 106 may include an electrostatic chuck (e-chuck) to secure the photomask 108. This is because the gas molecules absorb EUV light, and the lithography system 100 for EUV lithography patterning is maintained in a vacuum environment to minimize EUV intensity loss. Herein, the terms “photomask,” “mask,” and “reticle” may be used interchangeably. In some embodiments, the photomask 108 is a reflective mask.

In some embodiments, the pellicle 200 may be positioned over the photomask 108. The pellicle 200 may protect the photomask 108 from particles and may keep the particles out of focus, so that the particles do not produce an image (which may cause defects on a wafer during the lithography process).

The projection optics module 110 may be configured for imaging the pattern of the photomask 108 onto a semiconductor wafer 116 secured on the substrate stage 112. In some embodiments, the projection optics module 110 includes refractive optics (such as for a UV lithography system). In some embodiments, the projection optics module 110 includes reflective optics (such as for an EUV lithography system). The light 101′ directed from the photomask 108, carrying the image of the pattern defined on the photomask 108, may be collected by the projection optics module 110. The illuminator 104 and the projection optics module 110 may be collectively referred to as an “optical module” of the lithography system 100.

In some embodiments, the semiconductor wafer 116 may be a bulk semiconductor wafer. For instance, the semiconductor wafer 116 may include a silicon wafer. The semiconductor wafer 116 may include silicon or another elementary semiconductor material, such as germanium. In some embodiments, the semiconductor wafer 116 may include a compound semiconductor. The compound semiconductor may include gallium arsenide, silicon carbide, indium arsenide, indium phosphide, another suitable material, or combinations thereof.

In some embodiments, the semiconductor wafer 116 includes a silicon-on-insulator (SOI) substrate. The SOI substrate may be fabricated using a separation by implantation of oxygen (SIMOX) process, a wafer bonding process, another applicable process, or a combination thereof. In some embodiments, the semiconductor wafer 116 includes an undoped substrate. However, in other embodiments, the semiconductor wafer 116 includes a doped substrate, such as a p-type substrate or an n-type substrate.

In some embodiments, the semiconductor wafer 116 includes various doped regions (not shown) depending on the design requirements of the semiconductor device structure. The doped regions may include, for example, p-type wells and/or n-type wells. In some embodiments, the doped regions are doped with p-type dopants. For example, the doped regions may be doped with boron or boron fluoride. In other embodiments, the doped regions are doped with n-type dopants. For example, the doped regions may be doped with phosphor or arsenic. In some embodiments, some of the doped regions are p-doped and other doped regions are n-doped.

In some embodiments, an interconnection structure may be formed over the semiconductor wafer 116. The interconnection structure may include multiple interlayer dielectric layers, including dielectric layers. The interconnection structure may also include multiple conductive features formed in the interlayer dielectric layers. The conductive features may include conductive lines, conductive vias, and/or conductive contacts.

In some embodiments, various device elements are formed in the semiconductor wafer 116. Examples of the various device elements may include transistors (e.g., metal oxide semiconductor field effect transistors (MOSFETs), complementary metal oxide semiconductor (CMOS) transistors, bipolar junction transistors (BJTs), high-voltage transistors, high-frequency transistors, p-channel and/or n-channel field effect transistors (PFETs and/or NFETs), diodes, or other suitable elements. Various processes may be used to form the various device elements, including deposition, etching, implantation, photolithography, annealing, and/or other applicable processes.

The device elements may be interconnected through the interconnection structure over the semiconductor wafer 116 to form integrated circuit devices. The integrated circuit devices may include logic devices, memory devices (e.g., static random access memory (SRAM) devices), radio frequency (RF) devices, input/output (I/O) devices, system-on-chip (SoC) devices, image sensor devices, other applicable devices, or a combination thereof.

In some embodiments, the semiconductor wafer 116 may be coated with a photoresist layer that is sensitive to EUV light. Various components including those described above may be integrated together and may be operable to perform lithography exposing processes.

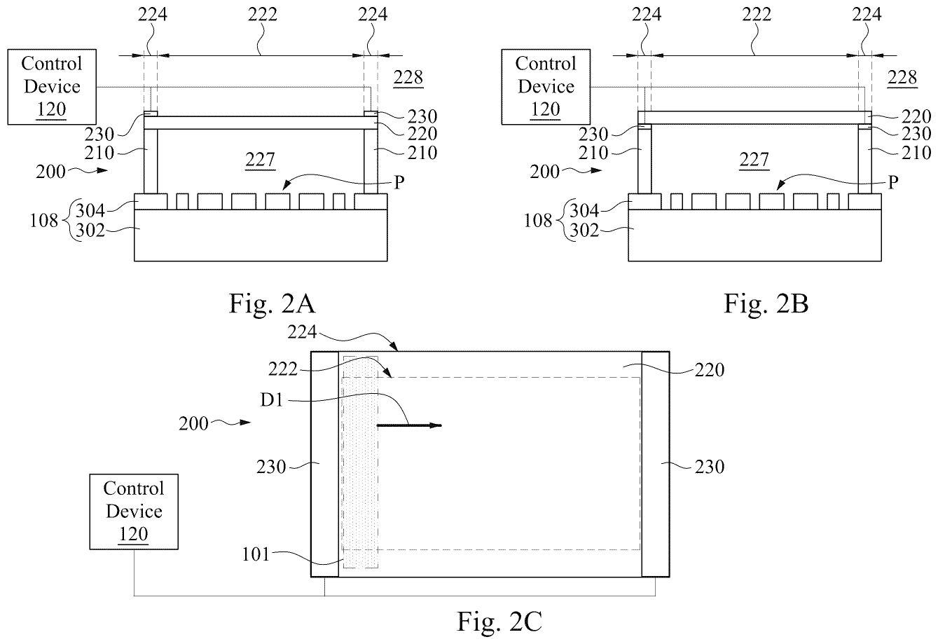

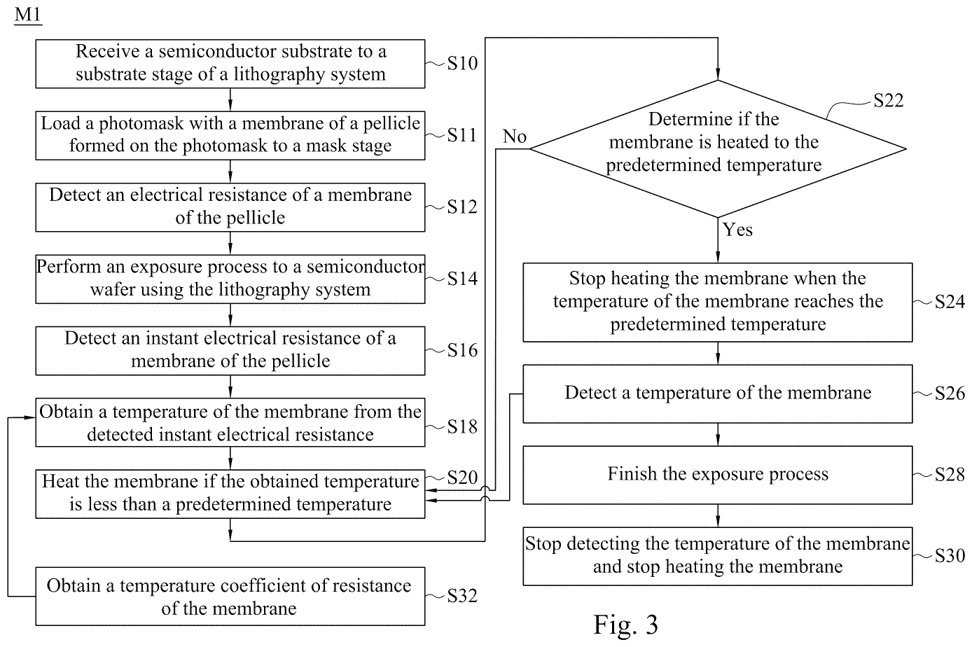

FIGS. 2A and 2B are cross-sectional views of the pellicle 200, the photomask 108, and the control device 120 of FIG. 1, according to some embodiments of the present disclosure. FIG. 2C is a top view of the pellicle 200 and the control device 120 of FIG. 2A. As illustrated in FIGS. 2A and 2B, the photomask 108 may include a mask substrate 302 and a mask pattern 304 positioned over the mask substrate 302. In some embodiments, the mask substrate 302 includes a transparent substrate, such as fused silica that is relatively free of defects, borosilicate glass, soda-lime glass, calcium fluoride, a low thermal expansion material, an ultra-low thermal expansion material, or other applicable materials. The mask pattern 304 may be positioned over the mask substrate 302 as discussed above and may be designed according to the integrated circuit features to be formed over a semiconductor wafer (e.g., semiconductor wafer 116 of FIG. 1) during a lithography process. The mask pattern 304 may be formed by depositing a material layer and patterning the material layer to have one or more openings where beams of radiation may travel through without being absorbed, and one or more absorption areas which may completely or partially block the beams of radiation.

The mask pattern 304 may include metal, metal alloy, metal silicide, metal nitride, metal oxide, metal oxynitride, or other applicable materials. Examples of materials that may be used to form the mask pattern 304 may include, but are not limited to, Cr, MoₓSi_{y}, TaₓSi_{y}, Mo, NbₓO_{y}, Ti, Ta, CrₓN_{y}, MoₓO_{y}, MoₓN_{y}, CrₓO_{y}, TiₓN_{y}, ZrₓN_{y}, TiₓO_{y}, TaₓN_{y}, TaₓO_{y}, SiₓO_{y}, NbₓN_{y}, ZrₓN_{y}, AlₓO_{y}N_{z}, TaₓB_{y}O_{z}, TaₓB_{y}N_{z}, AgₓO_{y}, AgₓN_{y}, Ni, NiₓO_{y}, NiₓO_{y}N_{z}, and/or the like. The compound x/y/z ratio is not limited.

As illustrated in FIGS. 2A and 2B, the pellicle 200 may be positioned over the photomask 108. The pellicle 200 and the photomask 108 may form an enclosed inner volume 227 that is enclosed by the pellicle 200 and the photomask 108. The pellicle 200 and the photomask 108 separate the inner volume 227 from an outer environment 228. In some embodiments, the pellicle 200 includes a pellicle frame 210 that may be positioned over at least one of the mask substrate 302 and the mask pattern 304. In some embodiments, the pellicle frame 210 may be formed from Si, SiC, SiN, glass, a low coefficient of thermal expansion material (such as an Al alloy, a Ti alloy, Invar, Kovar, or the like), another suitable material, or combinations thereof. In some embodiments, suitable processes for forming the pellicle frame 210 may include machining processes, sintering processes, photochemical etching processes, other applicable processes, or combinations thereof.

The pellicle 200 further includes a membrane 220 extending over the pattern region P of the photomask 108 to protect the pattern region P from contaminant particles. Particles unintentionally deposited on the pattern region P of the photomask 108 may introduce defects and result in degradation of the transferred patterns. Particles may be introduced by any of a variety of ways, such as during, a cleaning process, and/or during handling of the photomask 108. By keeping the contaminant particles out of the focal plane of the photomask 108, a high fidelity pattern transfer from the photomask 108 to the semiconductor wafer 116 (FIG. 1) can be achieved.

The membrane 220 includes an image region 222 which is the portion of the membrane 220 through which incident and/or reflected EUV radiation or light 101 passes. In some embodiments, the membrane 220 is a transparent membrane transparent to electromagnetic radiation, such as EUV radiation. In some embodiments, the membrane 220 has an EUV transmittance of more than about 96.5%. The membrane 220 may be opaque to some electromagnetic wavelengths, such as infrared or visible radiation and transparent to other electromagnetic wavelengths, such as EUV radiation or X-ray radiation. The membrane 220 may be made of poly-Si, SiN, carbon nanotubes (CNT), or other suitable materials. Further, the membrane 220 may include coating materials such as Ru, SiN, boron nitride nanotubes (BNNT), or other metals and/or dielectric layers that can be deposited on the top of the membrane 220 to enhance thermal, mechanical, and/or chemical stability during the exposure process.

During an exposure process, the light 101 emitted from the light source 102 projects to the photomask 108 through the pellicle 200. Therefore, the membrane 220 of the pellicle 200 is heated by the light 101. The light 101 may cause huge thermal stress in the membrane 220, which may suffer deformation such as cracking or wrinkling. Further, the thermal stress may lower the transmittance of the membrane 220, affecting the exposure efficiency of the lithography system 100. Therefore, some embodiments of this disclosure provide methods for temperature controlling of the membrane 220 to improve the thermal stress issues during the exposure process.

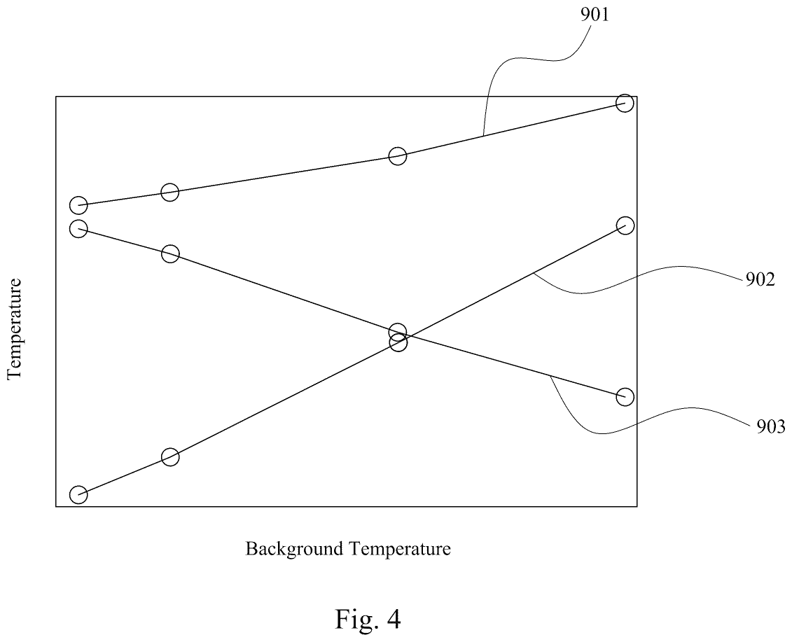

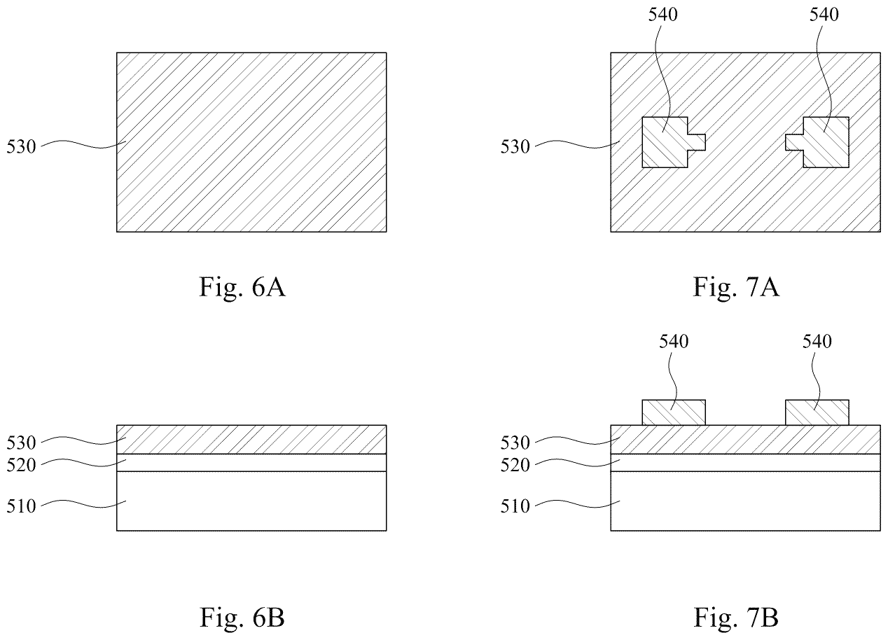

FIG. 3 is a flowchart illustrating a method M1 for temperature controlling of the membrane 220 in accordance with some embodiments. Various operations of the method M1 are discussed in association with at least FIGS. 1-2C and 5A-5B. It is noted that each of the methods presented below is merely an example, and not intended to limit the present disclosure beyond what is explicitly recited in the claims. Additional operations may be provided before, during, and after each of the methods. Some operations described may be replaced, eliminated, or moved around for additional embodiments of the transport methods. Additionally, for clarity and ease of explanation, some elements of the figures have been simplified. FIGS. 5A-5B are partial views of the pellicle 200 and the control device 120 during various stages of processing the temperature controlling according to the method M1.

The operation S10 of the method M1 includes receiving a semiconductor substrate to a substrate stage of a lithography system, and the operation S11 of the method M1 includes loading a photomask with a membrane of a pellicle formed on the photomask to a mask stage of the lithography system. As shown in FIG. 1, the semiconductor wafer 116 is received to the substrate stage 112 of the lithography system 100, and the photomask 108 with the membrane 220 of the pellicle 200, which is formed on the photomask 108, is loaded on the mask stage 106 of the lithography system 100. In some embodiments, the pellicle 200 is placed on the photomask 108 and covers a front-side of the photomask 108. That is, the mask pattern 304 is between the pellicle 200 and the mask substrate 302.

As shown in FIGS. 2A-2C, the pellicle 200 includes the pellicle frame 210, the membrane 220, and conductive electrodes 230. The pellicle frame 210 attaches a border region 224 of the membrane 220, and the conductive electrodes 230 are on a surface of the membrane 220. Specifically, the membrane 220 has an image region 222 and the border region 224 surrounding the image region 222. The border region 224 overlaps and is connected to the pellicle frame 210, and the light 101 emitted from the light source 102 is able to pass through the image region 222 to be incident the mask pattern 304 of the photomask 108. The conductive electrodes 230 are on the border region 224 and on opposite sides of the image region 222. In the embodiments of FIG. 2A, the conductive electrodes 230 are positioned above the membrane 220 on a side of the membrane 220 opposite to a side of the membrane 220 that is in contact with the pellicle frame 210. In some other embodiments, e.g., FIG. 2B, the conductive electrodes 230 are between the pellicle frame 210 and the membrane 220. In some embodiments, the conductive electrodes 230 may be formed of a conductive material such as titanium, palladium, platinum, nickel, combinations of these, or the like. For example, each of the conductive electrodes 230 includes a first conductive layer in contact with the membrane 220 and a second conductive layer over the first conductive layer and thicker than the first conductive layer. In some embodiments, the first conductive layer is a titanium layer, and the second conductive layer is a palladium layer.

The operation S12 of the method M1 includes detecting an electrical resistance of a membrane of the pellicle. In FIGS. 1 and 5A, the control device 120 of the lithography system 100 is electrically connected to the conductive electrodes 230 of the pellicle 200. The control device 120 is configured to provide or apply a test current I1 to the conductive electrodes 230 and thus to the membrane 220. The test current I1 flows from one of the conductive electrodes 230, through the membrane 220, and to the another one of the conductive electrodes 230. The control device 120 is then configured to measure the voltage dropping across the membrane 220 to obtain the electrical resistance of the membrane 220. Therefore, an electrical resistance (e.g., the electrical resistance R₀ mentioned in operation S18) of the membrane 220 at an initial temperature (e.g., at room temperature T₀ mentioned in operation S18) is obtained.

The operation S14 of the method M1 includes performing an exposure process to a semiconductor wafer using the lithography system. As shown in FIG. 1, during the exposure process, the light 101 is emitted from the light source 102, propagates through the illuminator 104 and the pellicle 200, and is then incident the photomask 108. The photomask 108 patterns the light 101, and the patterned light 101′ then propagates through the pellicle 200 and the projection optics module 110 and projects onto the semiconductor wafer 116.

In some embodiments, as shown in FIGS. 2A-2C, as the light 101 is incident the membrane 220 (and thus the mask pattern 304), the light 101 scans the image region 222 of the membrane 220 (and thus the mask pattern 304) in a first direction D1. In some embodiments, the conductive electrodes 230 are arranged in the first direction D1 as shown in FIG. 2C. Therefore, the lithography system 100 is also called a scanner.

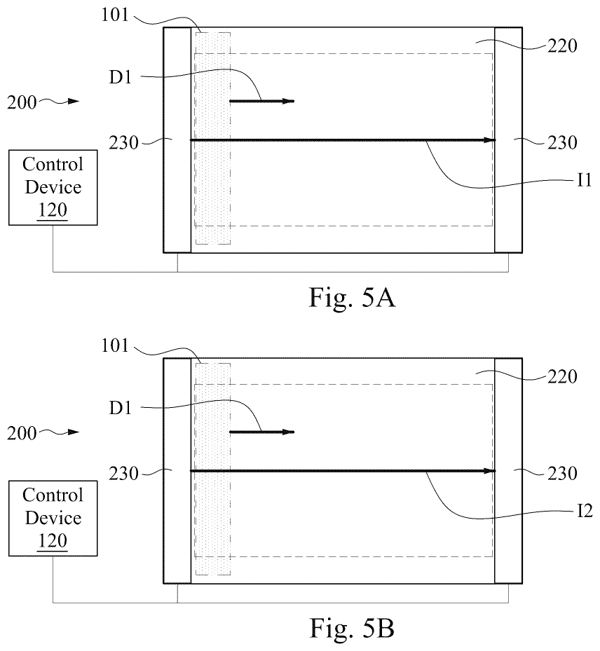

FIG. 4 is a graph illustrating maximum temperatures Tₘₐₓ, minimum temperatures Tₘᵢₙ, and temperature differences ΔT between the maximum temperatures and the minimum temperatures of the membrane 220 under different background temperatures. Reference is made to FIGS. 1, 2C, and 4. Specifically, prior to the exposure process, the membrane 220 has a background temperature (or an initial temperature) that is substantially the same as the ambient temperature. The minimum temperatures Tₘᵢₙ of the membrane 220 (denoted by line 902 in FIG. 4) refers to the temperature of the membrane 220 without emitted by the light 101 during the exposure process, and the maximum temperatures Tₘₐₓ of the membrane 220 (denoted by line 901 in FIG. 4) refers to the maximum temperature of the membrane 220 emitted by the light 101 during the exposure process. As shown in FIG. 4, the temperature difference ΔT (denoted by line 903 in FIG. 4) decreases as the background temperature increases.

When the light 101 passes through the membrane 220 of the pellicle 200, the membrane 220 absorbs the heat generated from the light 101. The membrane 220 is heated up by the light 101, and the temperature of the membrane 220 is raised. If the temperature of the membrane 220 is raised too fast (i.e., the temperature difference ΔT is high), the thermal stress in the membrane 220 may be huge, and the membrane 220 may suffer deformations. Further, the transmission capabilities of the membrane 220 may decrease when the thermal stress is huge. Therefore, a temperature controlling process is performed to improve the thermal stress issue of the membrane 220.

The operation S16 of the method M1 includes detecting an instant electrical resistance of the membrane of the pellicle. Prior to controlling the temperature of the membrane 220, the instant temperature of the membrane 220 during the exposure process is obtained. In some embodiments, the electrical resistance of the membrane 220 is a function of temperature. That is, the electrical resistance of the membrane 220 varies in response to changes in the temperature of the membrane 220, which is called a temperature coefficient of resistance (TCR). Therefore, in some embodiment, the instant temperature of the membrane 220 can be obtained by measuring the instant electrical resistance of the membrane 220. In some embodiments, the TCR of the membrane 220 is in a range from about 0.001 K⁻¹ to about 0.005 K⁻¹. If the TCR of the membrane 220 is lower than about 0.001 K⁻¹, the accuracy of the measured electrical resistance and thus the corresponding temperature of the membrane 220 (described in the operation S18) will be insufficient.

During the operation S16, the control device 120 provides the test current I1 to the conductive electrodes 230 as shown in FIG. 5A. The control device 120 is then configured to measure the voltage dropping across the membrane 220 to obtain the instant electrical resistance of the membrane 220. In some embodiments, a time duration for detecting the electrical resistance (i.e., applying the test current I1) is longer than a time duration of the light 101 scanning the image region 222 of the membrane 220 at least once. As shown in FIG. 2C, the size of the light beam of the light 101 is smaller than an area of the image region 222 of the membrane 220. The light 101 may locally heat up the membrane 220 if the light 101 does not scan the image region 222, and the temperature distribution of the membrane 220 may be spatially nonuniform. Therefore, after one or several times of the scans, the measured electrical resistance reflects the average electrical resistance of the membrane 220.

The operation S18 of the method M1 includes obtaining a temperature of the membrane from the detected instant electrical resistance. As mentioned above, with the TCR of the membrane 220, the instant temperature of the membrane 220 can be obtained or estimated from the measured instant electrical resistance. The equation is shown as follow:

$$R = {R}_{0} ⋆ ( 1 + α ⋆ ( {T}_{avg} - {T}_{0} ) ) .$$

R refers to the measured instant electrical resistance, To refers to the temperature of the membrane 220 in the initial state (e.g., at room temperature), R₀ refers to the electrical resistance of the membrane 220 in the initial state (e.g., at room temperature), a refers to the temperature coefficient of resistance of the membrane 220, and T_{avg} is the estimated instant temperature of the membrane 220. The estimated temperature is therefore corresponding to a particular light power of the light source 102.

The operation S20 of the method M1 includes heating the membrane if the obtained temperature is less than a predetermined temperature. As mentioned above and in FIG. 4, the temperature difference ΔT decreases as the background temperature of the membrane 220 increases. Therefore, in some embodiments, the control device 120 is configured to provide or apply a heating current I2 to the conductive electrodes 230 and thus the membrane 220 if the obtained temperature is less than a predetermined temperature to Joule heat the membrane 220 as shown in FIG. 5B. The heating current I2 is higher than the test current I1 (see FIG. 5A) because that the test current I1 is used to obtain the instant temperature of the membrane 220 and not to change the temperature of the membrane 220.

The value of the heating current I2 depends on the estimated temperature of the membrane 220. The heating current I2 decreases as the estimated temperature increases. In some embodiments, the predetermined temperature is in a range of about 50° C. and about 600° C. If the predetermined temperature is greater than about 600° C., the membrane 220 may be damaged; if the predetermined temperature is lower than about 50° C., the temperature difference ΔT may cause high thermal stress in the membrane 220. The predetermined temperature is further dependent on the material of the membrane 220. For example, if the membrane 220 is able to withstand high temperature, the predetermined temperature may be in a range of about 50° C. and about 1000° C.

The operation S22 of the method M1 includes determining if the membrane is heated to the predetermined temperature. During the heating process, the control device 120 may optionally in-situ detect the temperature of the membrane 220. Specifically, the control device 120 may stop providing the heating current I2 and then start to provide the test current I1. Subsequently, the control device 120 detects the electrical resistance of the membrane 220 and then estimates the temperature of the membrane 220. The details thereof are described in the operations S16 and S18, and, therefore, a description in this regard will not be repeated hereinafter.

If the estimated temperature of the membrane 220 does not reach the predetermined temperature, the control device 120 provides the heating current I2 again, but the value of the heating current I2 is adjusted according to the new estimated temperature. If the estimated temperature of the membrane 220 reaches the predetermined temperature, the method M1 goes to the operation S24. In some embodiments, when the membrane 220 is at the predetermined temperature, the temperature difference ΔT is in a range of 0° C. and about 200° C. The thermal stress may be huge if the temperature difference ΔT is higher than about 200° C. Specifically, the thermal stress of the membrane 220 is dependent on the temperature of the membrane 220, and also on the coefficient of thermal expansion, the Young's modulus, and/or Poisson's ratio of the membrane 220. The thermal stress may not exceed the tensile strength of the material of the membrane 220. Therefore, the temperature difference ΔT is material dependent.

The operation S24 of the method M1 includes stopping heating the membrane when the temperature of the membrane reaches the predetermined temperature. For example, the control device 120 stops providing or applying the heating current I2, such that the membrane 220 is not heated anymore. Therefore, the membrane 220 is at the predetermined temperature.

The operation S26 of the method M1 includes detecting a temperature of the membrane. In some embodiments, during the exposure process, the light 101 may not project to the membrane 220 all the time. For example, the light source 102 may stop providing the light 101 when the photomask 108 is moved, when the semiconductor wafer 116 is moved, or during other situations. The temperature of the membrane 220 may be reduced if the light 101 does not projected on the membrane 220. As such, the control device 120 may optionally perform the operation S26 to obtain the temperature of the membrane 220. The details for obtaining the temperature of the membrane 220 are described in the operations S16 and S18, and, therefore, a description in this regard will not be repeated hereinafter.

If the obtained temperature of the membrane 220 is lower than the predetermined temperature, the method M1 then go back to the operation S20. The control device 120 provides the heating current I2 to heat the membrane 220 until the temperature of the membrane 220 reaches the predetermined temperature. If the obtained temperature of the membrane 220 is substantially the predetermined temperature, the control device 120 takes no action about heating the membrane 220. The operation S26 may be performed multiple times, depending on the time duration of the exposure process.

The operation S28 of the method M1 includes finishing the exposure process. When the exposure process for the semiconductor wafer 116 (or a batch of the semiconductor wafers 116) is complete, the light source 102 stops providing the light 101, and the semiconductor wafer 116 can be transported out of the lithography system.

The operation S30 of the method M1 includes stopping detecting the temperature of the membrane and stopping heating the membrane. After the exposure process, the control device 120 may stop detecting or monitoring the temperature of the membrane 220 and also stop heating the membrane 220. Stated another way, the temperature controlling processes (e.g., the operations S16-S26) may be continuously performed during the exposure process.

In some embodiments, the TCR of the membrane 220 can be obtained prior to performing the temperature controlling processes or at least prior to performing the operation S18. The operation S32 of the method M1 includes obtaining a temperature coefficient of resistance of the membrane. For example, a plurality of test devices including channel structures, which are made of substantially the same material as the membrane 220, may be manufactured, and testing processes are performed to test the test devices under different temperatures. The TCR of the channel structures (and thus the membrane 220) can be obtained by measuring the electrical resistances of the channel structures under different temperatures.

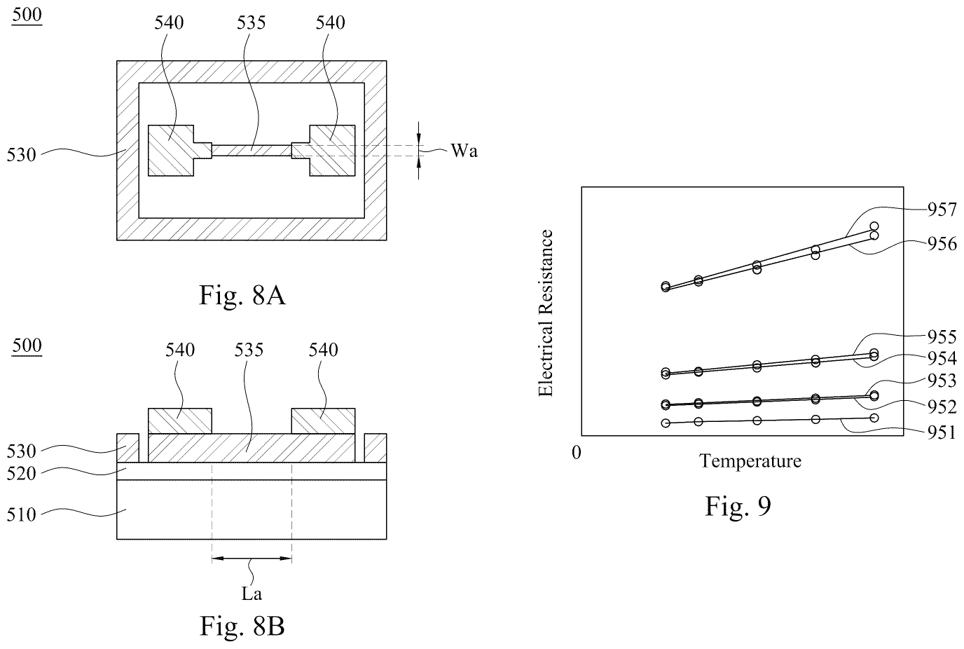

FIGS. 6A-8B illustrate top views (the “A” figures) and cross-sectional views (the “B” figures) of intermediate stages in the formation of a test device 500 in accordance with some embodiments of the present disclosure. Reference is made to FIGS. 6A and 6B. A dielectric layer 520 is deposited over a substrate 510. In some embodiments, the substrate 510 may include silicon (Si). Alternatively, the substrate 510 may include germanium (Ge), silicon germanium (SiGe), a III-V material (e.g., GaAs, GaP, GaAsP, AlInAs, AlGaAs, GaInAs, InAs, GalnP, InP, InSb, and/or GaInAsP; or combinations thereof) or other appropriate semiconductor materials. The dielectric layer 520 may be an oxide layer (e.g., SiO₂), a nitride layer, an oxynitride layer, or other suitable materials. The dielectric layer 520 may be formed using CVD, including LPCVD and PECVD, PVD, ALD, or other suitable processes.

A membrane layer 530 is formed over the dielectric layer 520. In some embodiments, the membrane layer 530 may be floating in a liquid (e.g., water) in advanced. Subsequently, the substrate 510 with the dielectric layer 520 is disposed in the liquid and under the membrane layer 530. The membrane layer 530 is then scooped up with the substrate 510 and the dielectric layer 520 and out of the liquid. The membrane layer 530 is made of materials substantially the same as the membrane 220 in FIGS. 2A-2C.

Reference is made to FIGS. 7A and 7B. Conductive electrodes 540 are then formed over the membrane layer 530. For example, a conductive layer is deposited over the membrane layer 530 by using CVD, including LPCVD and PECVD, PVD, ALD, or other suitable processes. The conductive layer is then patterned to be the conductive electrodes 540. In some embodiments, the conductive layer is patterned by using lift-off processes, dry etching processes, wet etching processes, or combinations thereof. In some embodiments, the conductive electrodes 540 is made of materials the same as or similar to the conductive electrodes 230 in FIGS. 2A-2C.

Reference is made to FIGS. 8A-8B. The membrane layer 530 is patterned to form a channel structure 535. In some embodiments, the membrane layer 530 is patterned by using an etching process, e.g., an O₂ plasma reactive-ion-etching process or other suitable etching process. In some embodiments, the flow rate of the O₂ is in a range of about 13 sccm and about 17 sccm, the processing pressure of the etching process is in a range of about 13 Pa and about 17 Pa, the RF power for the plasma is in a range of about 235 W and about 265 W, and a time duration for the etching process is in a range of about 110 seconds and about 130 seconds. The channel structure 535 forms a current flowing path between the conductive electrodes 540. The channel structure 535 has a channel length La and a channel width Wa.

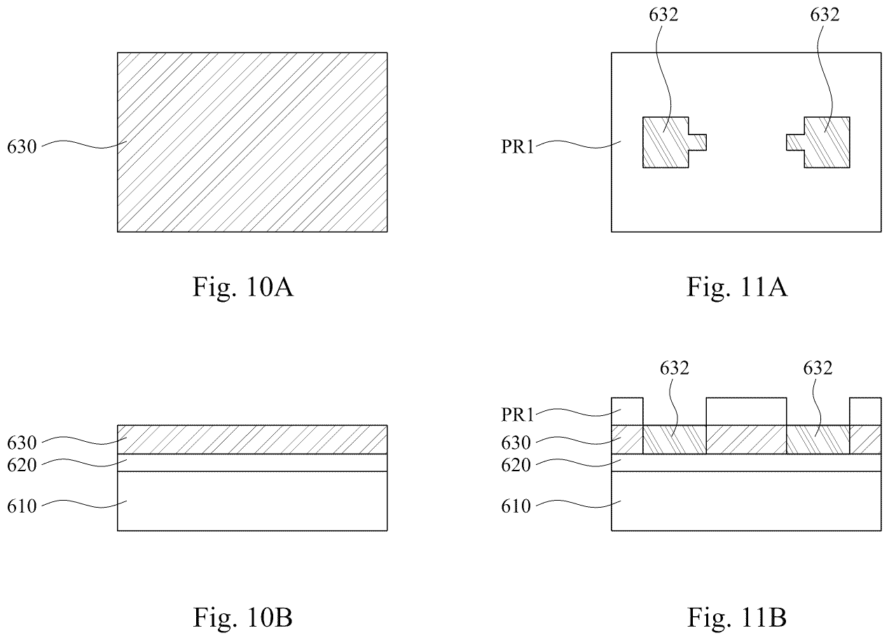

FIG. 9 is a plot of electrical resistance vs. temperature of the test devices with difference channel lengths and/or channel widths. The test devices 500 in FIGS. 8A and 8B are manufactured with different channel lengths and/or different channel widths. The test devices 500 with different channel sizes are then heated by using a heater, and the corresponding electrical resistances of the test devices 500 under different temperatures are measured to extract the average TCR of the channel structures 535 (which is CNT in FIG. 9).

Line 951 represents the electrical resistance vs. temperature of a test device with a channel length L1 and a channel width W1, line 952 represents the electrical resistance vs. temperature of a test device with a channel length L2 and a channel width W1, line 953 represents the electrical resistance vs. temperature of a test device with a channel length L1 and a channel width W2, lines 954 and 955 represent the electrical resistance vs. temperature of a test device with a channel length L3 and a channel width W1, and lines 956 and 957 represent the electrical resistance vs. temperature of a test device with a channel length L3 and a channel width W2. The channel length L3 is greater than the channel length L2, and the channel length L2 is greater than the channel length L1. The channel width W1 is greater than the channel width W2.

The equation to extract the TCR is shown as follow:

$$R = {R}_{0} ⋆ ( 1 + α ⋆ ( T - {T}_{0} ) ) .$$

R refers to the measured electrical resistance under temperature T, T₀ refers to the temperature of the channel structure 535 in the initial state (e.g., at room temperature), R₀ refers to the electrical resistance of the channel structure 535 in the initial state (e.g., at room temperature), a refers to the TCR of the channel structure 535. Each of the lines 951-957 corresponds to a TCR (in a range of about 0.0040 K⁻¹ to about 0.0056 K⁻¹), and the average TCR of the channel structure 535 can be obtained by the TCRs of the lines 951-957.

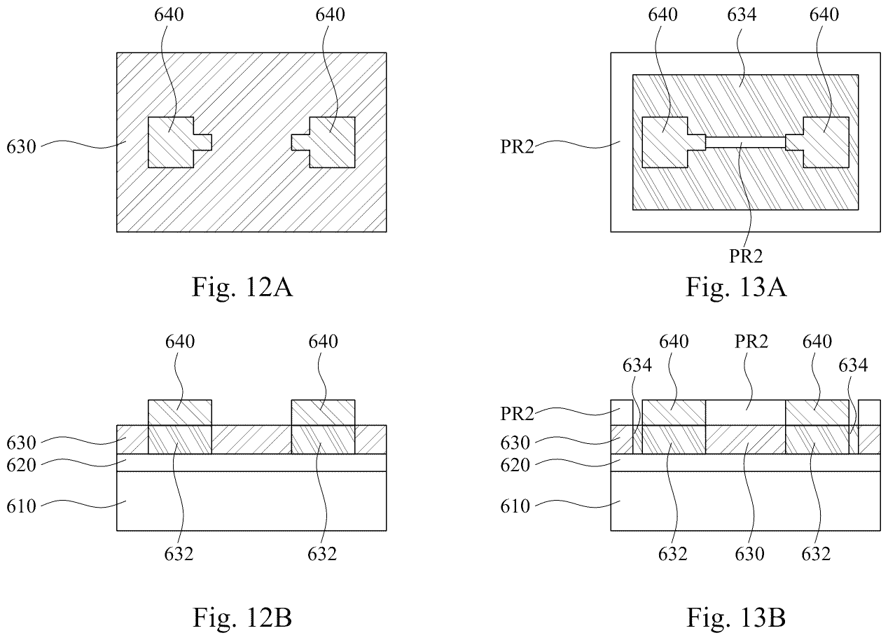

FIGS. 10A-14B illustrate top views (the “A” figures) and cross-sectional views (the “B” figures) of intermediate stages in the formation of a test device 600 in accordance with some embodiments of the present disclosure. Reference is made to FIGS. 10A and 10B. A dielectric layer 620 is deposited over a substrate 610. Materials, configurations, dimensions, processes and/or operations regarding the substrate 610 are similar to or the same as the substrate 510 described in FIGS. 6A and 6B, and materials, configurations, dimensions, processes and/or operations regarding the dielectric layer 620 are similar to or the same as the dielectric layer 520 described in FIGS. 6A and 6B.

A membrane layer 630 is formed over the dielectric layer 620. In some embodiments, the membrane layer 630 may be floating in a liquid (e.g., water) in advanced. Subsequently, the substrate 610 with the dielectric layer 620 is disposed in the liquid and under the membrane layer 630. The membrane layer 630 is then scooped up with the substrate 610 and the dielectric layer 620 and out of the liquid. The membrane layer 630 is made of a material substantially the same as the membrane 220 in FIGS. 2A-2C. For example, the membrane layer 630 is made of BNNT-coated CNT mesh network.

Reference is made to FIGS. 11A and 11B. A photoresist layer PR1 is formed over the membrane layer 630, and the photoresist layer PR1 exposes portions of the membrane layer 630. An etching process is performed to remove BNNT in the membrane layer 630. For example, the etching process is performed by using XeF₂ as an etching gas. XeF₂ selectively removes the BNNT and fluorinates the CNTs, such that the etched portions of the membrane layer 630 includes fluorinated CNTs 632. The fluorinated CNTs 632 has a greater electrical contact with the following formed conductive electrodes 640 (see FIGS. 12A and 12B) than the remaining membrane layer 630.

Reference is made to FIGS. 12A and 12B. Conductive electrodes 640 are formed over the fluorinated CNTs 632. For example, a conductive layer is deposited over the fluorinated CNTs 632 and the photoresist layer PR1 (see FIGS. 11A and 11B), and a lift-off process is performed to remove portions of the conductive layer. The remaining portions of the conductive layer form the conductive electrodes 640. Thereafter, the photoresist layer PR1 is removed.

Reference is made to FIGS. 13A and 13B. Another photoresist layer PR2 is formed over the membrane layer 630. The photoresist layer PR2 exposes the conductive electrodes 640 and a portion of the membrane layer 630. Thereafter, an etching process is performed to remove BNNT in the exposed portion of the membrane layer 630. For example, the etching process is performed by using XeF₂ as an etching gas. XeF₂ selectively removes the BNNT and fluorinates the CNTs, such that the etched portions of the membrane layer 630 includes fluorinated CNTs 634.

Reference is made to FIGS. 14A and 14B. The fluorinated CNTs 634 is etched to form a channel structure 635 including the fluorinated CNTs 632 and a portion 633 of the membrane layer 630 between the fluorinated CNTs 632. In some embodiments, the fluorinated CNTs 634 is removed by using an etching process, e.g., an O₂ plasma reactive-ion-etching process or other suitable etching process. The channel structure 635 forms a current flowing path between the conductive electrodes 640. The channel structure 635 has a channel length Lb and a channel width Wb.

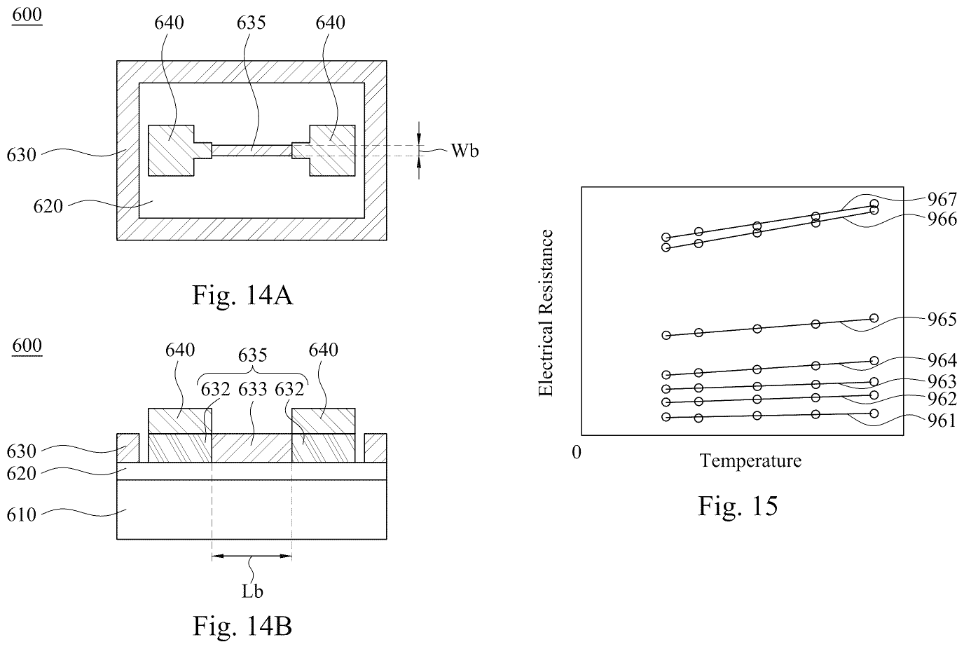

FIG. 15 is a plot of electrical resistance vs. temperature of the test devices 600 with difference channel lengths and/or channel widths. The test device 600 in FIGS. 14A and 14B are manufactured with different channel lengths and/or different channel widths. The test devices 600 with different channel sizes are then heated by using a heater, and the corresponding electrical resistances of the test devices 600 under different temperatures are measured to extract the average TCR of the channel structures 635 (which is BNNT coated CNT in FIG. 15).

Line 961 represents the electrical resistance vs. temperature of a test device with a channel length L1 and a channel width W1, line 962 represents the electrical resistance vs. temperature of a test device with a channel length L2 and a channel width W1, line 963 represents the electrical resistance vs. temperature of a test device with a channel length L1 and a channel width W2, line 964 represents the electrical resistance vs. temperature of a test device with a channel length L3 and a channel width W1, line 965 represents the electrical resistance vs. temperature of a test device with a channel length L2 and a channel width W2, and lines 966 and 967 represent the electrical resistance vs. temperature of a test device with a channel length L3 and a channel width W2. The channel length L3 is greater than the channel length L2, and the channel length L2 is greater than the channel length L1. The channel width W1 is greater than the channel width W2. Also, each of the lines 961-967 corresponds to a TCR (which is in a range of about 0.0021 K⁻¹ and about 0.0032 K⁻¹), and the average TCR of the channel structure 635 can be obtained by the TCRs of the lines 961-967.

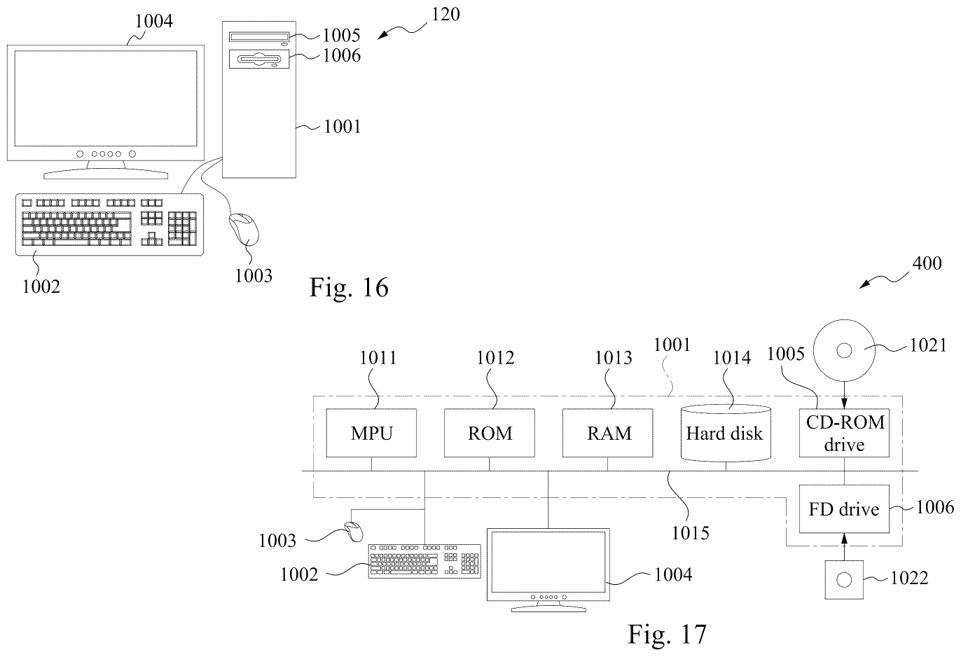

As explained above, the control device 120 is used to control the current supplied to the pellicle 200, and thus, the temperature of the membrane 220. In some embodiments, the control device 120 is a computer system. FIGS. 16 and 17 illustrate a computer system 400 for applying current to the individual conductive electrodes 230 in accordance with various embodiments of the disclosure. The control device 120 can also be used to control the heating operations S20. In some embodiments, the control device 120 is a module of a larger computer system that controls the other functions of the photolithographic exposure apparatus, including movement of the stepper/scanner, vacuum atmosphere, and the EUV radiation exposure of the photoresist-coated substrate. FIG. 16 is a schematic view of the computer system 400 that controls the current flowing through the membrane 220.

As shown in FIG. 16, the computer system 400 is provided with a computer 1001 including an optical disk read only memory (e.g., CD-ROM or DVD-ROM) drive 1005 and a magnetic disk drive 1006, a keyboard 1002, a mouse 1003 (or other similar input device), and a monitor 1004 in some embodiments.

FIG. 17 is a diagram showing an internal configuration of the computer system 400. In FIG. 17, the computer 1001 is provided with, in addition to the optical disk drive 1005 and the magnetic disk drive 1006, one or more processors 1011, such as a micro-processor unit (MP) or a central processing unit (CPU); a read-only memory (ROM) 1012 in which a program, such as a boot up program is stored; a random access memory (RAM) 1013 that is connected to the processors 1011 and in which a command of an application program is temporarily stored, and a temporary electronic storage area is provided; a hard disk 1014 in which an application program, an operating system program, and data are stored; and a data communication bus 1015 that connects the processors 1011, the ROM 1012, and the like. Note that the computer 1001 may include a network card (not shown) for providing a connection to a computer network such as a local area network (LAN), wide area network (WAN) or any other useful computer network for communicating data used by the computer system 400.

The programs for causing the computer system 400 to execute the method for controlling the heating of the membrane 220 are stored in an optical disk 1021 or a magnetic disk 1022, which is inserted into the optical disk drive 1005 or the magnetic disk drive 1006, and transmitted to the hard disk 1014. Alternatively, the programs are transmitted via a network (not shown) to the computer system 400 and stored in the hard disk 1014. At the time of execution, the programs are loaded into the RAM 1013. The programs are loaded from the optical disk 1021 or the magnetic disk 1022, or directly from a network in various embodiments.

The stored programs do not necessarily have to include, for example, an operating system (OS) or a third-party program to cause the computer 1001 to execute the methods disclosed herein. The program may only include a command portion to call an appropriate function (module) in a controlled mode and obtain desired results in some embodiments.

The control device 120 is configured to provide control data to the system components and receive process and/or status data from those system components. For example, in some embodiments, the control device 120 includes a microprocessor, a memory (e.g., volatile or non-volatile memory), and a digital I/O port capable of generating control voltages sufficient to communicate and activate inputs to the processing system. In addition, a process recipe may be stored in the control device 120. Furthermore, the control device 120 is configured to analyze the process and/or status data, to compare the process and/or status data with target process and/or status data, and to use the comparison to change a process and/or control a system component. In addition, the control device 120 is configured to analyze the process and/or status data, to compare the process and/or status data with historical process and/or status data, and to use the comparison to predict, prevent, and/or declare a fault or alarm.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that the temperature of the pellicle membrane can be in-situ controlled to reduce the thermal stress caused by the radiation or light of the lithography system. Furthermore, the transmission capability of the membrane can be maintained. Also, since the conductive electrodes are placed at the border region of the membrane, the conductive electrodes do not cover the image region of the membrane.

According to some embodiments, a method includes receiving a semiconductor substrate to a substrate stage of a lithography system. A photomask with a membrane of a pellicle formed on the photomask is loaded to a mask stage of the lithography system. Light is illuminated, by using a light source of the lithography system, on the membrane and the photomask to perform an exposure process on the semiconductor substrate. A temperature of the membrane of the pellicle is obtained during performing the exposure process. The membrane is heated if the obtained temperature of the membrane is less than a predetermined temperature.

According to some embodiments, a method includes placing a pellicle in a lithography system to cover a photomask. A light is emitted to pass through the pellicle to the photomask. The light is patterned by the photomask and then projects onto a semiconductor wafer. A test current is applied to a membrane of the pellicle to obtain a temperature of the membrane during emitting the light. A heating current is applied to the membrane to heat the membrane. A value of the heating current depends on the obtained temperature of the membrane.

According to some embodiments, a system includes a mask stage, a pellicle, a substrate stage, a light source, and a control device. The mask stage is configured to secure a photomask. The pellicle is positioned over the photomask. The pellicle includes a membrane and conductive electrodes. The membrane has an image region and a border region surrounding the image region. The conductive electrodes are on the border region of the membrane and on opposite sides of the image region of the membrane. The substrate stage is configured to secure a semiconductor wafer. The light source is configured to emit a light to pass through the image region of the membrane of the pellicle to the photomask, the light being patterned by the photomask and then propagating to the semiconductor wafer. The control device is electrically connected to the conductive electrodes and is configured to applying a test current to the conductive electrodes to detect a temperature of the membrane and applying a heating current to the conductive electrodes to heat the membrane.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
receiving a semiconductor substrate to a substrate stage of a lithography system;
loading a photomask with a membrane of a pellicle formed on the photomask to a mask stage of the lithography system;
illuminating light, by using a light source of the lithography system, on the membrane and the photomask to perform an exposure process on the semiconductor substrate;
during performing the exposure process, obtaining a temperature of the membrane of the pellicle; and
heating the membrane if the obtained temperature of the membrane is less than a predetermined temperature.

2. The method of claim 1, wherein obtaining the temperature of the membrane of the pellicle comprises:
detecting an instant electrical resistance of the membrane; and
obtaining the temperature from the detected instant electrical resistance.

3. The method of claim 2, wherein detecting the instant electrical resistance comprises:
providing a test current across the membrane; and
detecting a voltage dropping across the membrane while providing the test current.

4. The method of claim 1, wherein the predetermined temperature is in a range of about 50° C. and about 600° C.

5. The method of claim 1, further comprising:
stopping heating the membrane when the temperature of the membrane reaches to the predetermined temperature.

6. The method of claim 5, further comprising:
after stopping heating the membrane, detecting the temperature of the membrane.

7. The method of claim 1, further comprising:
finishing performing the exposure process; and
stopping obtaining the temperature of the membrane.

8. The method of claim 1, further comprising:
obtaining a temperature coefficient of resistance of the membrane prior to obtaining the temperature of the membrane of the pellicle.

9. The method of claim 8, wherein obtaining the temperature coefficient of resistance of the membrane comprises:
manufacturing a test device comprising a channel structure having substantially the same materials as the membrane; and
obtaining electrical resistances of the channel structure under different temperatures to obtain the temperature coefficient of resistance.

10. The method of claim 8, wherein the temperature coefficient of resistance of the membrane is in a range from about 0.001 K⁻¹ to about 0.005 K⁻¹.

11. A method comprising:
placing a pellicle in a lithography system to cover a photomask;
emitting a light to pass through the pellicle to the photomask, wherein the light is patterned by the photomask and then projects onto a semiconductor wafer;
applying a test current to a membrane of the pellicle to obtain a temperature of the membrane during emitting the light; and
applying a heating current to the membrane to heat the membrane, wherein a value of the heating current depends on the obtained temperature of the membrane.

12. The method of claim 11, wherein the heating current is higher than the test current.

13. The method of claim 11, further comprising scanning the light over an image region of the membrane.

14. The method of claim 13, wherein a time duration of applying the test current is longer than a time duration of scanning the light over the image region of the membrane once.

15. The method of claim 11, further comprising stopping applying the heating current when the temperature of the membrane reaches a predetermined temperature.

16. The method of claim 15, wherein when the temperature of the membrane reaches the predetermined temperature, a temperature difference of the membrane is in a range of 0° C. and about 200° C.

17. The method of claim 15, further comprising:
after stopping applying the heating current, applying the test current again to obtain the temperature of the membrane.

18. The method of claim 11, further comprising:
detecting an electrical resistance of the membrane prior to emitting the light to pass through the pellicle to the photomask.

19. A system comprising:
a mask stage configured to secure a photomask;
a pellicle positioned over the photomask, wherein the pellicle comprises:
a membrane having an image region and a border region surrounding the image region; and
conductive electrodes on the border region of the membrane and on opposite sides of the image region of the membrane;
a substrate stage configured to secure a semiconductor wafer;
a light source configured to emit a light to pass through the image region of the membrane of the pellicle to the photomask, the light being patterned by the photomask and then propagating to the semiconductor wafer; and
a control device electrically connected to the conductive electrodes and configured to:
applying a test current to the conductive electrodes to detect a temperature of the membrane; and
applying a heating current to the conductive electrodes to heat the membrane.

20. The system of claim 19, wherein the control device is further configured to stop applying the heating current when the membrane reaches a predetermined temperature.
